(19) United States
(12) Patent Application Publication
(10) Pub. No.: US 2025/0304385 A1
(43) Pub. Date: Oct. 2, 2025

(54) MAGNETIC LEVITATION APPARATUS, METHOD OF CONTROLLING MAGNETIC LEVITATION APPARATUS, MANUFACTURING SYSTEM, AND METHOD OF MANUFACTURING ARTICLE

(71) Applicant: CANON KABUSHIKI KAISHA, Tokyo (JP)

(72) Inventor: MASAKI FUJITA, Tokyo (JP)

(21) Appl. No.: 19/090,183

(22) Filed: Mar. 25, 2025

(30) Foreign Application Priority Data
Apr. 1, 2024 (JP) 2024-059199

(51) Int. Cl. B65G 54/02; H02K 41/03

(52) U.S. Cl. CPC B65G 54/02; H02K 41/031; B65G 2812/99

(57) ABSTRACT

Disclosed is a magnetic levitation apparatus that includes a mover including first and second magnetic force units for a magnetic force to act therebetween; a guide unit for supporting the mover; and a control unit. One of the first and second magnetic force units includes a coil, and the other includes a permanent magnet. The control unit controls a current flowing through the coil to control a position and attitude of the mover. When the mover is in contact with the guide unit, the control unit starts position control with respect to the mover in a levitation direction in which the mover is levitated from the guide unit and, when the mover is in contact with the guide unit after the position control, starts zero power control with respect to the mover to levitate the mover from the guide unit.

### BACKGROUND

### Field

The present disclosure relates to a magnetic levitation apparatus, a method of controlling a magnetic levitation apparatus, a manufacturing system, and a method of manufacturing an article.

### Description of the Related Art

In general, a transport apparatus is used in a production line for assembling industrial products, a semiconductor exposure apparatus, and the like. In particular, the transport apparatus in the production line transports a workpiece such as a component between a plurality of stations within a factory-automated production line or between the production lines. In some cases, the transport apparatus is used as a transport unit in a process apparatus. A transport apparatus formed of a movable magnet type linear motor has already been proposed as the transport apparatus.

In the transport apparatus formed of the movable magnet type linear motor, a guide device such as a linear guide involving mechanical contact is used. However, the transport apparatus using the guide device such as the linear guide has had a problem in that the productivity has been degraded by contaminants generated from a sliding portion of the linear guide, for example, a deteriorating component, lubricating oil of a rail or a bearing, a volatilized matter of the lubricating oil, and the like. Further, there has been a problem in that, at the time of high-speed transport, the friction of the sliding portion is increased and thus the life of the linear guide is reduced.

In view of the above, in Japanese Patent Application Laid-Open No. 2020-28212, discusses a magnetic levitation transport apparatus capable of transporting a mover in a non-contact manner. In the magnetic levitation transport apparatus, the mover is levitated and transported by an electromagnetic force generated between a permanent magnet group arranged along a transport direction of the mover and a coil group opposed thereto by supplying a current to the coil group.

Further, in general, in the magnetic levitation transport apparatus, in order to reduce the power consumption for supporting the mover in a non-contact manner, there has been known a zero power control system of controlling a coil current value so as to converge to the vicinity of zero.

For example, Japanese Patent Application Laid-Open No. 2012-125067 discusses a gap sensor for detecting a predetermined gap between a mover and a magnet support unit is mounted, and current control of an electromagnet is performed so as to maintain a length of the gap such that a weight of the mover and an attraction force caused by a permanent magnet are precisely balanced with each other. That is, in Japanese Patent Application Laid-Open No. 2012-125067, the levitation control is performed by setting the gap length of the mover such that an excitation current of the electromagnet becomes zero.

In the zero power control system, control is performed such that a current flowing through the coil becomes zero. Accordingly, the zero power control system cannot be used under a state in which the mover is supported in contact by the guide at the time of power off or the like. Thus, at the time of transitioning the mover from the contact state to the non-contact state with respect to the guide, a position instruction in a levitation direction is provided through the control of keeping the gap length constant. In Japanese Patent Application Laid-Open No. 2012-125067, switching to the zero power control is executed by estimating a reaction force from the guide which supports the mover in contact, and checking the transition to the non-contact state through detection of the fact that the estimated value of the reaction force has become zero or a relatively small value.

However, in the levitation control method as described in Japanese Patent Application Laid-Open No. 2012-125067, when a mover having a large size and a low rigidity is to be controlled, at the time of transition to the non-contact state which is the levitation state, the mover may oscillate due to the natural vibration of the mover or the resonance with the guide. Accordingly, there is a risk in that a transporting object mounted on the mover receives an impact or the transition to the levitation state of the mover fails.

### SUMMARY

The present disclosure provides a magnetic levitation apparatus and a method of controlling the magnetic levitation apparatus with which a mover can be stably levitated even when the mover has a large size and a low rigidity.

An aspect of the present disclosure provides a magnetic levitation apparatus that includes a mover including a first magnetic force unit; a second magnetic force unit positioned opposed to the first magnetic force unit, for a magnetic force to act between the second magnetic force unit and the first magnetic force unit; a guide unit configured to support the mover; and a control unit configured to control a position and an attitude of the mover. One of the first magnetic force unit or the second magnetic force unit includes a coil. Another one of the first magnetic force unit or the second magnetic force unit includes a magnet. The control unit is configured to control a current flowing through the coil to control the position and the attitude of the mover. The control unit also is configured to start, when the mover is in contact with the guide unit, position control with respect to the mover in a levitation direction, and start, when the mover is in contact with the guide unit after the position control, zero power control with respect to the mover to levitate the mover from the guide unit.

Further features of the present disclosure will become apparent from the following description of exemplary embodiments with reference to the attached drawings.

### BRIEF DESCRIPTION OF THE DRAWINGS

FIG. 1 is a schematic view illustrating a transport apparatus according to a first embodiment of the present disclosure.

FIG. 2 is a schematic view illustrating a cross section of the transport apparatus according to the first embodiment of the present disclosure.

FIG. 3 is a schematic view illustrating a control system for controlling the transport apparatus according to the first embodiment of the present disclosure.

FIG. 4 is a schematic view illustrating a coil and a configuration related to the coil in the transport apparatus according to the first embodiment of the present disclosure.

FIG. 5 is a schematic view illustrating a method of controlling a position and attitude of a mover in the transport apparatus according to the first embodiment of the present disclosure.

FIG. 6 is a schematic diagram illustrating control blocks for controlling the position and attitude of the mover in the transport apparatus according to the first embodiment of the present disclosure.

FIG. 7A is a Bode plot showing an example of a frequency characteristic of the mover in the transport apparatus according to the first embodiment of the present disclosure.

FIG. 7B is a Bode plot showing an example of the frequency characteristic of the mover in the transport apparatus according to the first embodiment of the present disclosure.

FIG. 8 is a schematic view illustrating the attitude of the mover during levitation transition in the transport apparatus according to the first embodiment of the present disclosure.

FIG. 9A is a schematic view illustrating a relationship between a force in a Z direction acting on the mover and a position in the Z direction in the transport apparatus according to the first embodiment of the present disclosure.

FIG. 9B is a schematic view illustrating the relationship between the force in the Z direction acting on the mover and the position in the Z direction in the transport apparatus according to the first embodiment of the present disclosure.

FIG. 9C is a schematic view illustrating the relationship between the force in the Z direction acting on the mover and the position in the Z direction in the transport apparatus according to the first embodiment of the present disclosure.

FIG. 9D is a graph showing the relationship between the force in the Z direction acting on the mover and the position in the Z direction in the transport apparatus according to the first embodiment of the present disclosure.

FIG. 10 is a graph showing transition of the position in the Z direction and a position in a Wx direction of the mover during execution of levitation control in the transport apparatus according to the first embodiment of the present disclosure.

FIG. 11A is a schematic view illustrating transition of the position and attitude of the mover during the execution of the levitation control in the transport apparatus according to the first embodiment of the present disclosure.

FIG. 11B is a schematic view illustrating the transition of the position and attitude of the mover during the execution of the levitation control in the transport apparatus according to the first embodiment of the present disclosure.

FIG. 11C is a schematic view illustrating the transition of the position and attitude of the mover during the execution of the levitation control in the transport apparatus according to the first embodiment of the present disclosure.

FIG. 12 is a schematic view illustrating control blocks for controlling a position and attitude of a mover in a transport apparatus according to a second embodiment of the present disclosure.

FIG. 13A is a schematic view illustrating transition of the position and attitude of the mover during execution of levitation control in the transport apparatus according to the second embodiment of the present disclosure.

FIG. 13B is a schematic view illustrating the transition of the position and attitude of the mover during the execution of the levitation control in the transport apparatus according to the second embodiment of the present disclosure.

FIG. 13C is a schematic view illustrating the transition of the position and attitude of the mover during the execution of the levitation control in the transport apparatus according to the second embodiment of the present disclosure.

FIG. 13D is a graph showing a relationship of a spring constant at each position of the mover in the transport apparatus according to the second embodiment of the present disclosure.

FIG. 14 is a flow chart illustrating a levitation sequence of the mover in the transport apparatus according to the second embodiment of the present disclosure.

FIG. 15 is a schematic view illustrating a rotational drive apparatus according to a third embodiment of the present disclosure.

### DESCRIPTION OF THE EMBODIMENTS

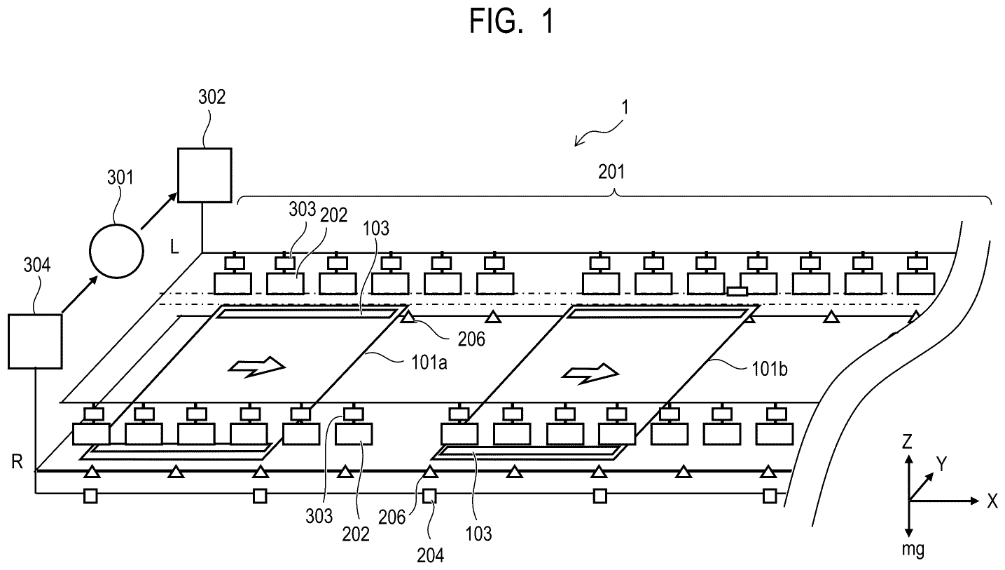

A magnetic levitation apparatus according to a first embodiment of the present disclosure is described with reference to FIG. 1 to FIG. 11C. In the present embodiment, a transport apparatus is described as an example of the magnetic levitation apparatus.

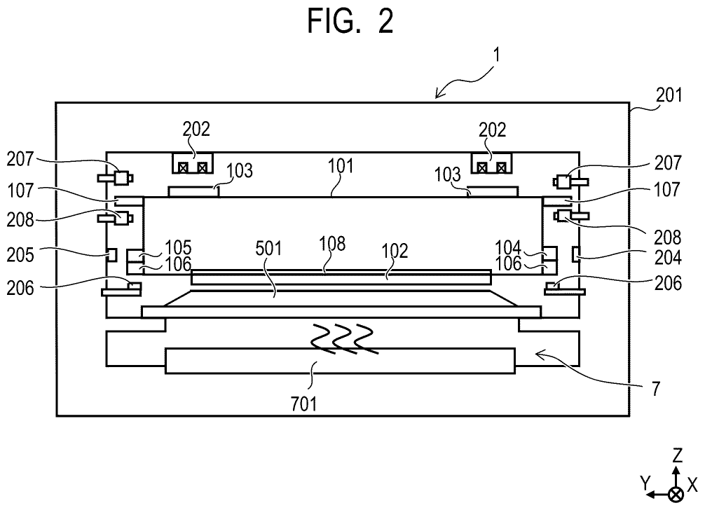

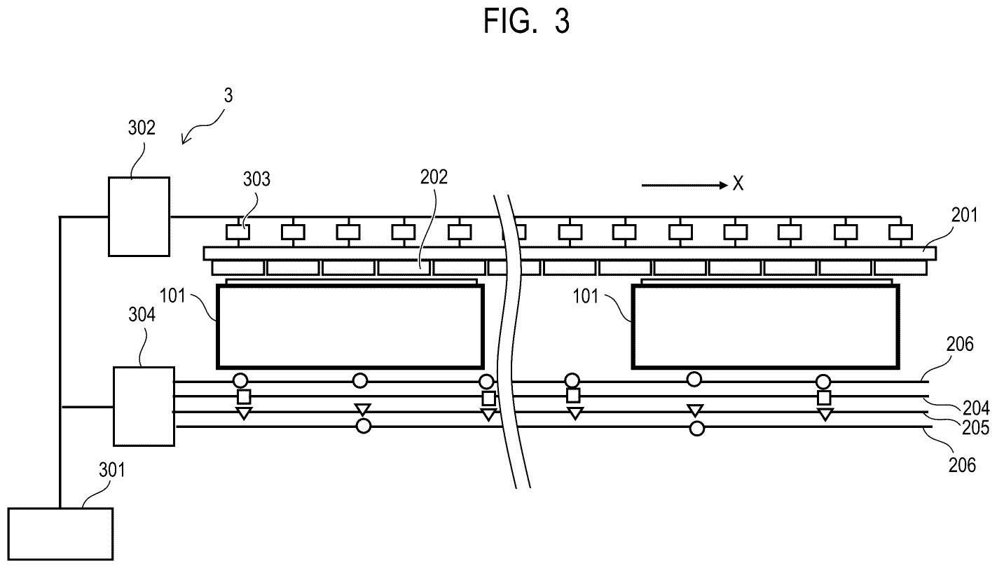

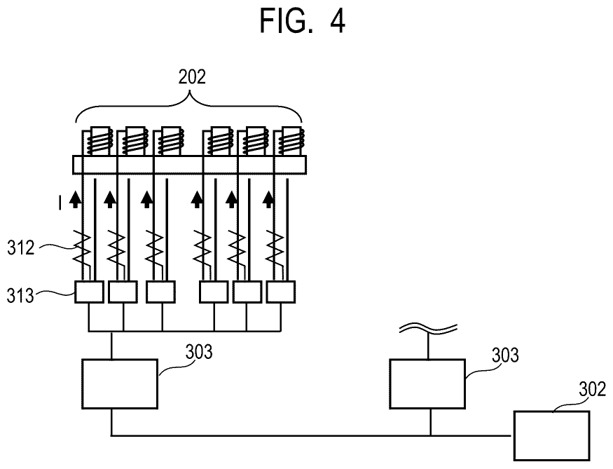

First, a configuration of a transport apparatus 1 according to the present embodiment is described with reference to FIG. 1 to FIG. 4. FIG. 1 and FIG. 2 are schematic views illustrating the configuration of the transport apparatus 1 including a mover 101 and a stator 201 in the present embodiment. Note that FIG. 1 and FIG. 2 extract and illustrate main parts of the mover 101 and the stator 201. FIG. 1 is a view of the mover 101 as viewed from diagonally above the mover 101. FIG. 2 is a cross-sectional view of the mover 101 and the stator 201 as viewed from an X direction, as described later. FIG. 3 is a schematic view illustrating a control system 3 in the transport apparatus 1. FIG. 4 is a schematic view illustrating a coil 202 and a configuration related to the coil 202.

As illustrated in FIG. 1 and FIG. 2, the transport apparatus 1 according to the present embodiment includes the mover 101 forming a carrier for transporting a workpiece, and the stator 201 forming a transport path. In FIG. 1, two movers 101a and 101b are illustrated as the mover 101. Further, the transport apparatus 1 includes an integration controller 301, a coil controller 302, a coil unit controller 303, and a sensor controller 304. In the following, a reference symbol including only the common number is used when it is not particularly required to distinguish components that may be present as a plurality of components, such as the mover 101 and the stator 201, and a lowercase alphabet is appended to a reference number as required so that the individuals are distinguished.

The transport apparatus 1 according to the present embodiment is a transport apparatus formed of a linear motor for transporting the mover 101 by generating an electromagnetic force between a permanent magnet 103 of the mover 101 and the coil 202 of the stator 201. Further, the transport apparatus 1 according to the present embodiment is a magnetic levitation type transport apparatus for levitating the mover 101 and transporting the mover 101 in a non-contact manner. In the transport apparatus 1, the permanent magnet 103 of the mover 101 and the coil 202 of the stator 201 function as magnetic force units for which a magnetic force acts therebetween.

The transport apparatus 1 according to the present embodiment forms a part of a manufacturing system further including a process apparatus for subjecting the workpiece transported by the mover 101 to work such as processing work and inspection work. In general, the transport apparatus is used in a production line for assembling industrial products, a semiconductor exposure apparatus, and the like. In particular, the transport apparatus in the production line transports a workpiece such as a component between a plurality of stations within a factory-automated production line or between the production lines. Further, in some cases, the transport apparatus is used as a transport apparatus in the process apparatus. The transport apparatus 1 according to the present embodiment may be used for such applications.

The transport apparatus 1 transports, for example, the mover 101 by the stator 201 to transport the workpiece held by the mover 101 to the process apparatus for subjecting the workpiece to work. The process apparatus is not particularly limited, and is, for example, a film formation apparatus such as a vapor deposition apparatus or a sputtering apparatus for forming a film on a substrate 102, as described later, which is the workpiece. The manufacturing system manufactures an article by subjecting the workpiece to work.

Now, coordinate axes, directions, and the like used in the following description are defined. First, an X axis is taken along a horizontal direction which is a transport direction of the mover 101, and the transport direction of the mover 101 is defined as the X direction. Further, a Z axis is taken along the vertical direction which is a direction orthogonal to the X direction, and the vertical direction is defined as a Z direction. The vertical direction is a direction of gravity (“mg” direction). Further, a Y axis is taken along a direction orthogonal to the X direction and the Z direction, and a direction orthogonal to the X direction and the Z direction is defined as a Y direction. The X direction and the Y direction are horizontal directions. Moreover, rotation about the X axis is represented by Wx, a rotation direction about the Y axis is defined as a Wy direction, and a rotation direction about the Z axis is defined as a Wz direction. Further, as displacement of the mover 101 in each direction, a position in the X direction is represented by X, a position in the Y direction is represented by Y, and a position in the Z direction is represented by Z. Further, as a rotation amount which is displacement of the mover 101 in each rotation direction, a rotation amount in the Wx direction is represented by Wx, a rotation amount in the Wy direction is represented by Wy, and a rotation amount in the Wz direction is represented by Wz. Further, a symbol “*” is used as a symbol for multiplication. Further, the center of the mover 101 is defined as an origin Oc, and a +Y side is described as an L-side, and a −Y side is described as an R-side. When a component positioned on the L-side and a component positioned on the R-side are to be distinguished, after the reference numeral, L indicating that the component is positioned on the L-side and R indicating that the component is positioned on the R-side are appended so that both of the components are distinguished. Note that the transport direction of the mover 101 is need not be the horizontal direction. Even in such a case, the transport direction can be defined as the X direction, and the Y direction and the Z direction can be similarly defined. Also note that the X direction, the Y direction, and the Z direction are not limited to directions that are orthogonal to each other, and can also be defined as directions intersecting with each other.

As indicated by the arrow of FIG. 1, the mover 101 is configured to be movable along the X direction which is the transport direction. The mover 101 includes the permanent magnet 103, a linear scale 104, a Y-target 105, a Z-target 106, and a stopper 107. The mover 101 has an upper surface and a lower surface positioned on a side opposite to the upper surface.

A plurality of permanent magnets 103 are mounted and installed on the upper surface of the mover 101 along the X direction respectively at R-side and L-side end portions. The plurality of permanent magnets 103 forming magnet groups respectively on the R-side and the L-side include a plurality of XZ magnet groups and a plurality of Y magnet groups. The XZ magnet group is a magnet group in which magnets having poles of the N pole and the S pole different from each other are alternately arranged side by side in the X direction. The Y magnet group is a magnet group in which magnets having poles of the N pole and the S pole different from each other are alternately arranged side by side in the Y direction. The N pole and the S pole described here are polarities of the upper surface of each permanent magnet 103. Note that the place to install the permanent magnets 103 and the number of permanent magnets 103 to be installed are not particularly limited, and can be changed as appropriate. The permanent magnet 103 functions as the magnetic force unit for which the magnetic force acts between the permanent magnet 103 and the coil 202 of the stator 201.

The linear scale 104, the Y-target 105, and the Z-target 106 are each mounted and installed in the mover 101 at a position that can be read by a linear encoder or a sensor which is installed on the stator 201. The linear encoder and the sensor referred to here include a linear encoder 204, a Y-sensor 205, and a Z-sensor 206, which are described later.

The stopper 107 is mounted and installed so as to protrude to the outer side in the Y direction from both side surfaces of the mover 101 facing the Y direction. An upper guide 207 and a lower guide 208, which are described later, are installed for the stopper 107 so as to be opposed to the stopper 107 from the upper side and the lower side in the Z direction.

The stator 201 includes the coil 202, the linear encoder 204, the Y-sensor 205, the Z-sensor 206, the upper guide 207, and the lower guide 208.

A plurality of coils 202 are mounted and installed along the X direction on the stator 201 at positions opposed to the permanent magnets 103 installed on the upper surface of the mover 101. Specifically, the plurality of coils 202 are arranged and installed in two rows along the X direction so as to be capable of being opposed from above along the Z direction to the two permanent magnets 103 installed at the respective R-side and L-side end portions on the upper surface of the mover 101. Note that the place to install the coils 202 and the number of coils 202 to be installed are not particularly limited, and can be changed as appropriate. The coil 202 functions as the magnetic force unit for which the magnetic force acts between the coil 202 and the permanent magnet 103 of the mover 101.

The stator 201 causes each coil 202 to which a current has been applied to generate an electromagnetic force between the coil 202 and the permanent magnet 103. In this manner, the mover 101 can move along the X direction while being levitated along the Z direction. The coil 202 includes a magnetic-body core, and assists a force in a raising direction acting on the mover 101 by a magnetic attraction force acting between the core and the permanent magnet 103.

The linear encoder 204, the Y-sensor 205, and the Z-sensor 206 function as a detection unit for detecting a position and attitude of the mover 101 moving along the transport direction of the mover 101.

The linear encoder 204 is mounted and installed on the stator 201 so as to be capable of reading the linear scale 104 installed on the mover 101. The linear encoder 204 reads the linear scale 104 to detect the position of the mover 101 relative to the linear encoder 204. The linear encoder 204 reads the linear scale 104 mounted on the mover 101.

The Y-sensor 205 is mounted and installed on the stator 201 so as to be capable of detecting a distance in the Y direction between the Y-sensor 205 and the Y-target 105 installed on the mover 101. The Z-sensor 206 is mounted and installed on the stator 201 so as to be capable of detecting a distance in the Z direction between the Z-sensor 206 and the Z-target 106 installed on the mover 101.

The upper guide 207 and the lower guide 208 are mounted and installed on the stator 201 along the X direction so as to be opposed to the stopper 107 mounted on the mover 101, from the upper side and the lower side in the Z direction. A plurality of upper guides 207 and a plurality of lower guides 208 are installed. The upper guide 207 is installed so as to be opposed to the stopper 107 from the upper side. The lower guide 208 is installed so as to be opposed to the stopper 107 from the lower side. At least one of the upper guide 207 and the lower guide 208 are a guide unit for restricting a movable range of the mover 101 in the Z direction by coming into contact with the stopper 107 in accordance with the position of the mover 101 in the Z direction. When the mover 101 is not levitated at the time of power off of the transport apparatus 1, or the like, the mover 101 is attracted to the upper guide 207 by the magnetic attraction force of the permanent magnet 103, or is supported by the lower guide 208 in contact with the lower guide 208. The upper guide 207 or the lower guide 208 supports the mover 101 in contact with the non-levitated mover 101.

For example, the mover 101 is transported while a workpiece is mounted or held on an upper side or a lower side thereof. Note that FIG. 2 illustrates a state in which the substrate 102 such as a glass substrate serving as the workpiece is held by a holding mechanism 108 provided on the lower surface of the mover 101. The mechanism for mounting or holding the workpiece on the mover 101 is not particularly limited, and a general mounting mechanism or holding mechanism such as a mechanical hook or an electrostatic chuck can be used.

Further, FIG. 2 illustrates a film formation apparatus 7 as an example of the process apparatus for subjecting the workpiece held by the mover 101 to work such as processing. The film formation apparatus 7 performs film formation by vapor deposition or the like on the substrate 102 held by the mover 101. The film formation apparatus 7 is incorporated and installed in the stator 201. The transport apparatus 1 and the film formation apparatus 7 form the manufacturing system.

The film formation apparatus 7 includes: a pattern mask 501 installed so as to be capable of being opposed to the substrate 102 held below the mover 101; and a film formation source 701 installed so as to be capable of being opposed to the substrate 102 via the pattern mask 501 on the lower side of the pattern mask 501. The film formation source 701 is a film formation source for releasing a film formation material for forming a film on the substrate 102. The pattern mask 501 is, for example, a mask foil provided with a predetermined opening pattern desired to be formed on a film to be formed. With the mover 101 being transported in the X direction, the substrate 102 held by the mover 101 is stopped in a state of being levitated in air above the pattern mask 501.

After the mover 101 is levitated and stopped at a predetermined position in the X direction and alignment between the substrate 102 and the pattern mask 501 is performed, the film formation material is released from the film formation source 701 arranged on the lower side of the pattern mask 501 so that a film is formed on the substrate 102. As described above, the workpiece is transported together with the mover 101, and the process apparatus performs work on the transported workpiece so that an article is manufactured from the workpiece. The process apparatus is not limited to the film formation apparatus 7, and may be an apparatus for subjecting the workpiece to work in accordance with the workpiece transported by the mover 101.

Next, a control system 3 for controlling the transport apparatus 1 according to the present embodiment is described with reference to FIG. 3 and FIG. 4. The control system 3 may form a part of the transport apparatus 1. FIG. 3 is a schematic view illustrating the control system 3 for controlling the transport apparatus 1 according to the present embodiment. FIG. 4 is a schematic view illustrating a connection configuration of the coil controller 302.

As illustrated in FIG. 3, the control system 3 includes the integration controller 301, the coil controller 302, and the sensor controller 304. The control system 3 functions as a control unit for controlling the transport apparatus 1 including the mover 101 and the stator 201. The coil controller 302 and the sensor controller 304 are connected to the integration controller 301 so that communication is allowed therebetween.

A plurality of coil unit controllers 303 are connected to the coil controller 302 so that communication is allowed therebetween. The coil controller 302 and the plurality of coil unit controllers 303 connected thereto are provided so as to correspond to each of the rows of the coils 202. The coil 202 is connected to each of the coil unit controllers 303.

As illustrated in FIG. 4, one or a plurality of coils 202 are connected to each of the coil unit controllers 303. A current sensor 312 and a current controller 313 are connected to the coil 202. The current sensor 312 detects a current value of a current flowing through the connected coil 202. The current controller 313 controls the amount of current flowing through the connected coil 202. Thus, the coil unit controller 303 controls the current amount of the connected coil 202.

The coil unit controller 303 gives an instruction of a desired current amount to the current controller 313 based on a current instruction value received from the coil controller 302. The current controller 313 detects a current value detected by the current sensor 312 to control the current amount so that a desired amount of current flows through the coil 202.

The plurality of linear encoders 204, the plurality of Y-sensors 205, and the plurality of Z-sensors 206 are connected to the sensor controller 304 so that communication is allowed therebetween.

The plurality of linear encoders 204 are mounted to the stator 201 at intervals at which one of the linear encoders 204 can measure the position of one mover 101 even during transport of the mover 101. Further, the plurality of Y-sensors 205 are mounted to the stator 201 at intervals at which two of the Y-sensors 205 can measure the Y-target 105 of the one mover 101. Further, the plurality of Z-sensors 206 are mounted to the stator 201 at intervals at which three of the two rows of Z-sensors 206 can measure the Z-target 106 of the one mover 101 and so as to form a plane.

The integration controller 301 determines the current instruction value to be applied to the plurality of coils 202 based on the output from the linear encoder 204, the Y-sensor 205, and the Z-sensor 206, and transmits the current instruction value to the coil controller 302. The coil controller 302 gives an instruction of the current value to the coil unit controller 303 as described above, based on the current instruction value from the integration controller 301. In this manner, the integration controller 301 functions as the control unit to transport the mover 101 along the stator 201 in a non-contact manner, and also control the attitude of the transported mover 101 in six axes.

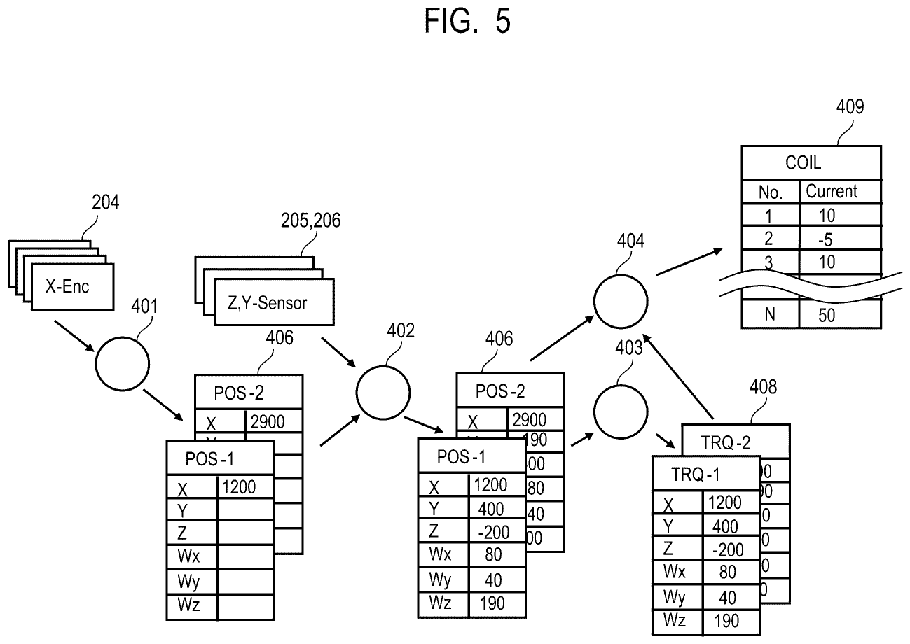

Next, a method of controlling the position and attitude of the mover 101 to be executed by the integration controller 301 is described with reference to FIG. 5. FIG. 5 is a schematic view illustrating the method of controlling the position and attitude of the mover 101 in the transport apparatus 1 according to the present embodiment. FIG. 5 shows the outline of the attitude control method for the mover 101, focusing mainly on the flow of its data. As described later, the integration controller 301 executes processing using a mover position calculation function 401, a mover attitude calculation function 402, a mover attitude control function 403, and a coil current calculation function 404. In this manner, the integration controller 301 controls the transport of the mover 101 while controlling the attitude of the mover 101 in six axes. Note that instead of using the integration controller 301, the coil controller 302 can be configured to execute processing similar to that performed by the integration controller 301.

First, the mover position calculation function 401 calculates the number of movers 101 and the positions of the movers 101 present above the stator 201 forming the transport path from information of measurement values, from the plurality of linear encoders 204 and the mounting positions thereof. In this manner, the mover position calculation function 401 updates mover position information (X) and number information of mover information 406 which is information on the mover 101. The mover position information (X) indicates a position in the X direction which is the transport direction of the mover 101 above the stator 201. The mover information 406 is prepared for each mover 101 above the stator 201, as indicated by, for example, POS-1, POS-2, . . . in FIG. 5.

Next, the mover attitude calculation function 402 identifies the Y-sensor 205 and the Z-sensor 206 that can measure each of the movers 101 from the mover position information (X) of the mover information 406 updated by the mover position calculation function 401. Next, the mover attitude calculation function 402 calculates attitude information (Y, Z, Wx, Wy, Wz) which is information on the attitude of each of the movers 101, based on the values output from the identified Y-sensor 205 and Z-sensor 206, and updates the mover information 406. The mover information 406 updated by the mover attitude calculation function 402 includes the mover position information (X) and the attitude information (Y, Z, Wx, Wy, Wz).

Next, the mover attitude control function 403 calculates application force information 408 for each of the movers 101 from the current mover information 406 including the mover position information (X) and the attitude information (Y, Z, Wx, Wy, Wz) and an attitude target value. The application force information 408 is information on a magnitude of the force to be applied to each of the movers 101. The application force information 408 includes information on three-axis components (Tx, Ty, Tz) of force and three-axis components (Twx, Twy, Twz) of torque of application torque Tq to be applied (described later). The application force information 408 is prepared for each of the movers 101 above the stator 201 as indicated by, for example, TRQ-1, TRQ-2, . . . in FIG. 5. Herein, the torque includes force and a moment of the force, and the torque in a direction along an axis such as the X direction, the Y direction, or the Z direction refers to the force.

In this case, Tx, Ty, and Tz which are the three-axis components of force are an X direction component, a Y direction component, and a Z direction component of the force, respectively. Further, Twx, Twy, and Twz which are the three-axis components of torque are a component about the X axis, a component about the Y axis, and a component about the Z axis of the torque, respectively. The transport apparatus 1 according to the present embodiment controls transport of the mover 101 while controlling the attitude of the mover 101 in six axes, by controlling those six-axis components (Tx, Ty, Tz, Twx, Twy, Twz) of the application torque Tq.

Next, the coil current calculation function 404 determines a current instruction value 409 to be applied to each coil 202, based on the application force information 408 and the mover information 406.

Thus, the integration controller 301 executes processing using the mover position calculation function 401, the mover attitude calculation function 402, the mover attitude control function 403, and the coil current calculation function 404 to determine the current instruction value 409. The integration controller 301 transmits the determined current instruction value 409 to the coil controller 302.

As described above, the integration controller 301 controls the current to be caused to flow through the coil 202, to control the position and attitude of the mover 101 in the X direction, the Y direction, the Z direction, the Wx direction, the Wy direction, and the Wz direction.

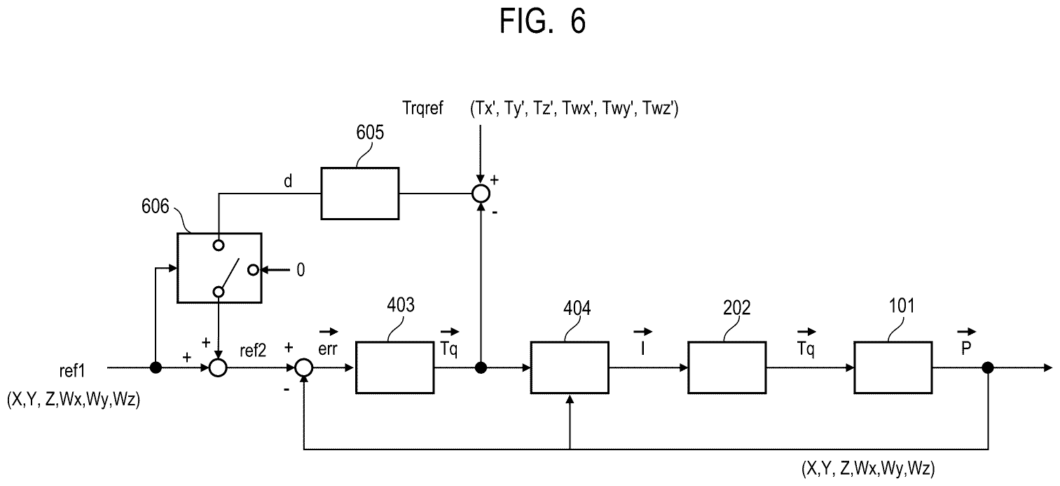

The control of the position and attitude of the mover 101 is further described in detail with reference to FIG. 6. FIG. 6 is a schematic diagram illustrating control blocks for controlling the position and attitude of the mover 101 in the transport apparatus 1 according to the present embodiment. The integration controller 301 executes control through the control blocks illustrated in FIG. 6.

In FIG. 6, a position and attitude P of the mover 101 has components of (X, Y, Z, Wx, Wy, Wz). A position instruction target value ref1 is used to give an instruction of the target value of (X, Y, Z, Wx, Wy, Wz). A deviation “err” is a deviation between the position instruction target value ref1 and the position and attitude P.

The mover attitude control function 403 calculates the desired application torque Tq to be applied to the mover 101, from the magnitude of the deviation “err,” the change in the deviation “err,” the integrated value of the deviation “err,” and the like.

The coil current calculation function 404 calculates the desired coil current I to be applied to the coil 202 in order to apply the application torque Tq to the mover 101, based on the application torque Tq and the position and attitude P. When the coil current I calculated as described above is applied to the coil 202, the application torque Tq acts on the mover 101 to change the position and attitude P of the mover 101 again.

Further, the integration controller 301 can further execute processing using a torque control function 605 to control the torque to be applied to the mover 101. The torque control function 605 calculates an operation amount “d” to a target value ref2, from an integrated value of a difference between the application torque Tq and an instruction torque Trqref. The instruction torque Trqref has components of Tx′, Ty′, Tz′, Twx′, Twy′, and Twz′ with respect to the six-axis components (Tx, Ty, Tz, Twx, Twy, Twz) of the application torque Tq. Tx′ is an instruction value of Tx, Ty′ is an instruction value of Ty, Tz′ is an instruction value of Tz, Twx′ is an instruction value of Twx, Twy′ is an instruction value of Twy, and Twz′ is an instruction value of Twz. The mover attitude control function 403 can calculate the application torque Tq to be applied to the mover 101 in consideration of the operation amount “d”. In this case, among the components of the instruction torque Trqref, when Tz′, Twx′, and Twy′ are set to zero, so-called zero power control can be executed in the Z direction, the Wx direction, and the Wy direction. Through the zero power control, the levitation control of the mover 101 can be performed at the position and attitude at which the gravity and the attraction force that act on the mover 101 are balanced with each other. In the present embodiment, the integration controller 301 can set among the components of the instruction torque Trqref, Tz′, Twx′, and Twy′ to zero, so as to use the torque control function 605 as a function for performing the zero power control.

Further, the integration controller 301 uses a switch 606 as a switching unit for switching between position control and zero power control as the control to be performed on the mover 101. In the position control, the position and attitude of the mover 101 is controlled so as to become a predetermined target value. The switch 606 outputs a value 0 or the operation amount “d” calculated by the torque control function 605, based on the value of the position instruction target value ref1. The output of the switch 606 is added to the position instruction target value ref1. In this manner, the target value of the position and attitude of the mover 101 is updated from ref1 to ref2.

In the control blocks illustrated in FIG. 6, when the output of the switch 606 is the value 0, the position and attitude of the mover 101 is controlled by the position control, and, when the output of the switch 606 is the operation amount “d”, the position and attitude of the mover 101 is controlled by the zero power control. With the control blocks being formed as described above, the position and attitude of the mover 101 can be controlled to a desired position and attitude.

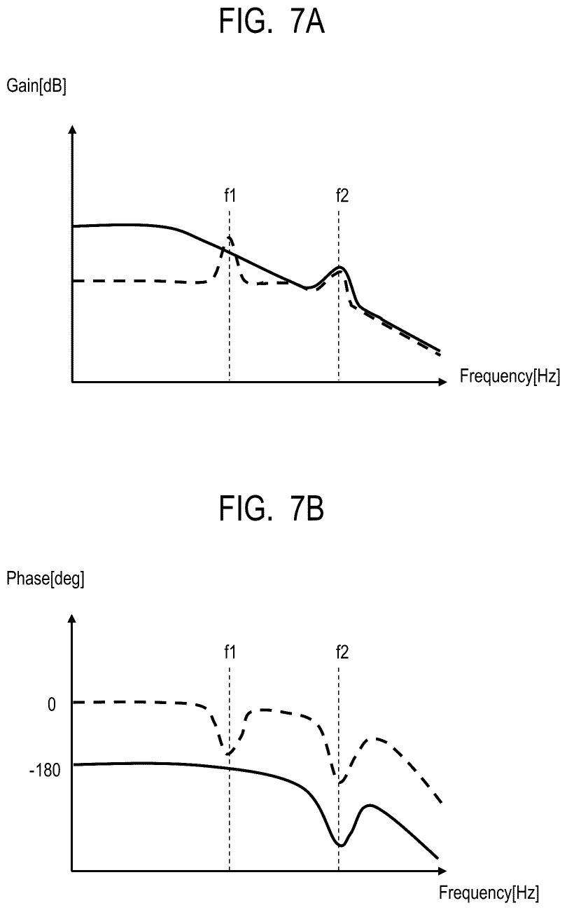

When the mover 101 in the state of being supported by the lower guide 208 is to be transitioned to a levitation state, the mover 101 may oscillate when the mover 101 is simply transitioned to the levitation state by the position control. Now, the mechanism of the oscillation of the mover 101 at the time of transitioning the mover 101 to the levitation state by the position control is described with reference to FIG. 7A, FIG. 7B, and FIG. 8. Note that, in this case, the mechanism of the oscillation is described while taking the Wx direction as an example, but a similar phenomenon may occur even in the Wy direction.

FIG. 7A and FIG. 7B are examples of a Bode plot representing a frequency characteristic of the mover 101 in the Wx direction. The vertical axis of the graph of FIG. 7A represents gain at the time when the application torque Tq is set as input and output is regarded as the position and attitude. The gain indicates a variation amount of the position with respect to variation of the application torque Tq, and is calculated by (“position P”/“application torque Tq”). The vertical axis of the graph of FIG. 7B represents difference between the phase of the application torque Tq and the phase of the position P. The horizontal axes of the graphs of FIG. 7A and FIG. 7B represent frequency. That is, the graphs of FIG. 7A and FIG. 7B represent the responsiveness of the position and attitude of the mover 101 represented on a frequency axis.

The broken line of FIG. 7A and FIG. 7B indicates an example of a frequency characteristic of the mover 101 placed on the lower guide 208. The solid line of FIG. 7A and FIG. 7B indicates an example of a frequency characteristic of the mover 101 in a non-contact state, that is, the mover 101 in the levitation state. The lower guide 208 has a natural frequency f1, and the mover 101 has a natural frequency f2. In the vicinity of the natural frequency, the gain characteristic is increased and the phase is delayed, and hence the mover 101 easily oscillates.

When the mover 101 is transitioned from the state of being in contact with the lower guide 208 to the levitation state, the mover 101 loses the natural frequency f1 and is increased in gain. In order to control the mover 101, it is required to adjust control parameters in consideration of the natural frequencies f1 and f2 and the change in the frequency characteristic at the time of transitioning from the contact state to the levitation state.

FIG. 8 is a schematic view illustrating the attitude of the mover 101 at the time of transitioning from the state of being placed on the lower guide 208 to the levitation state. Ideally, mounting heights of an L-side coil 202L and an R-side coil 202R are desired to be horizontal. However, for example, when the transport apparatus 1 has a large size, the mounting heights of the L-side coil 202L and the R-side coil 202R may not be horizontal due to an assembly error or the like.

A situation in which the mover 101 is levitated when the mounting height of the R-side coil 202R is lower than that of the L-side coil 202L as illustrated in FIG. 8 is described as an example. When the mover 101 is levitated by the position control, the integration controller 301 first gives a raising instruction to raise the mover 101 in the Z direction. In this case, as illustrated in FIG. 8, as compared to a distance between the L-side coil 202L and a permanent magnet 103L opposed thereto, a distance between the R-side coil 202R and a permanent magnet 103R opposed thereto is shorter. Accordingly, the mover 101 is raised while being inclined in a form of being lifted from the R-side. That is, the mover 101 is raised while being displaced in a negative direction in the Wx direction. At this time, the mover 101 is brought into non-contact with an R-side lower guide 208R, but the mover 101 is raised while being held in contact with an L-side lower guide 208L. As the mover 101 is raised, the frequency characteristic of the mover 101 gradually comes closer to the levitation state indicated by the solid line in FIG. 7A and FIG. 7B from the contact state indicated by the broken line in FIG. 7A and FIG. 7B. That is, the gain is increased as the mover 101 is raised. Further, the number of lower guides 208 in contact with the mover 101 is reduced, and thus the spring performance of the entire lower guide 208 is decreased. Thus, the natural frequency f1 of the lower guide 208 is decreased. At this time, when the inclination of the mover 101 in the Wx direction is large, the mover 101 is continuously raised while being held in contact with the lower guide 208L. Accordingly, the mover 101 comes closer to the frequency characteristic of the non-contact state while having the natural frequency f1, and oscillates at the natural frequency f1.

In order to prevent the mover 101 from oscillating due to the natural vibration at the natural frequency f1, the inclination of the mover 101, that is, the displacement of the mover 101 in the Wx direction is required to be suppressed. In order to suppress this displacement, it is required to set high control parameters such as a proportional gain and an integral gain to be set in the mover attitude control function 403, and enhance the responsiveness of the mover 101 with respect to the deviation “err.” However, when the responsiveness of the mover 101 is enhanced, the responsiveness to the natural frequency f2 is also enhanced, and hence the mover 101 may oscillate due to the natural vibration at the natural frequency f2.

In contrast, the transport apparatus 1 according to the present embodiment achieves stable levitation of the mover 101 while suppressing or preventing oscillation of the mover 101 caused by the natural vibration described above. The transport apparatus 1 according to the present embodiment uses the zero power control to achieve the stable levitation of the mover 101. Now, the levitation control of the mover 101 in the transport apparatus 1 according to the present embodiment is described.

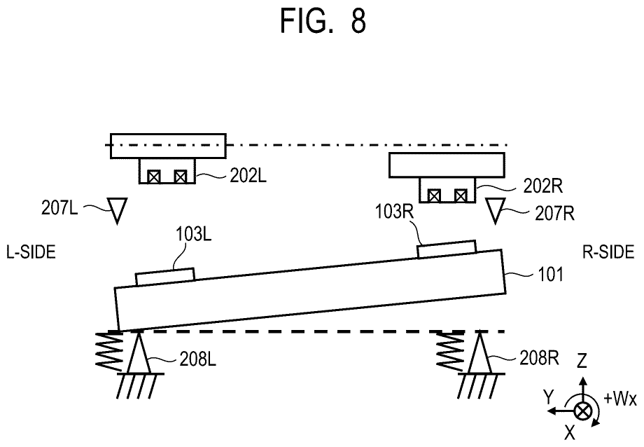

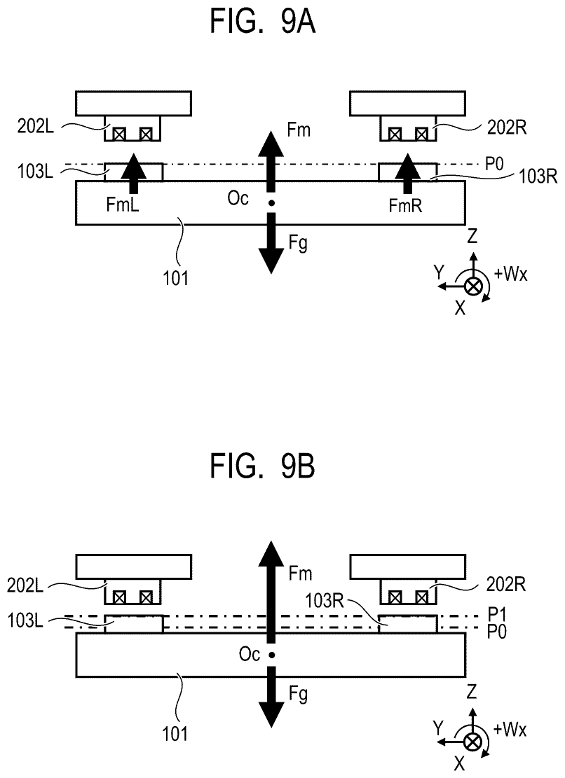

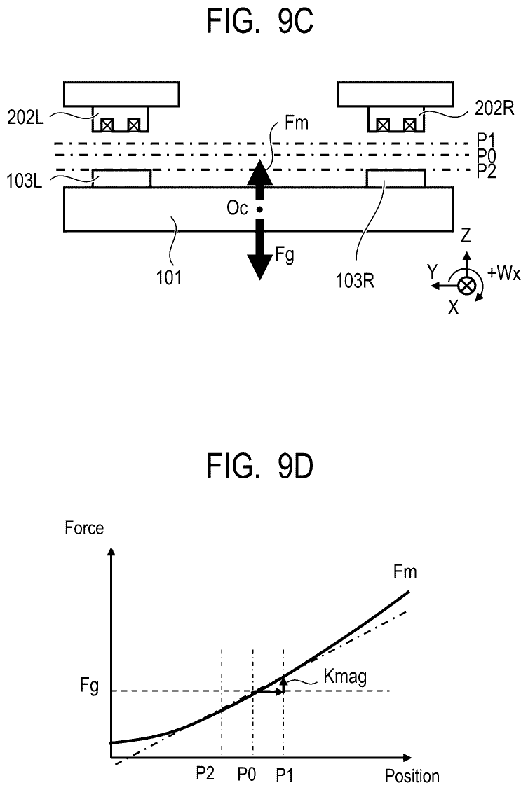

First, before the levitation control of the mover 101 is described, the position of equilibrium of the mover 101 in the transport apparatus 1 is described with reference to FIG. 9A to FIG. 9D. FIG. 9A to FIG. 9C are schematic views illustrating the relationship between the force in the Z direction acting on the mover 101 and the position in the Z direction, and are views of the mover 101 and the coil 202 as viewed in the X direction. FIG. 9D is a graph showing the relationship between the force in the Z direction acting on the mover 101 and the position in the Z direction.

A position P0 in the Z direction illustrated in FIG. 9A is a position at which a gravity Fg and an attraction force Fm that act on the mover 101 are balanced with each other (hereinafter referred to as “position of equilibrium”). The attraction force Fm is a magnetic attraction force caused by the permanent magnet 103. When the mover 101 is positioned at the position of equilibrium P0, a relationship of “gravity Fg”= “attraction force Fm” is satisfied.

A position P1 in the Z direction illustrated in FIG. 9B is a position at which a gap in the Z direction between the permanent magnet 103 and the coil 202 is smaller than that at the position of equilibrium P0. When the mover 101 is positioned at the position P1, a relationship of “gravity Fg”<“attraction force Fm” is satisfied.

A position P2 in the Z direction illustrated in FIG. 9C is a position at which the gap between the permanent magnet 103 and the coil 202 is larger than that at the position of equilibrium P0. When the mover 101 is positioned at the position P2, a relationship of “gravity Fg”>“attraction force Fm” is satisfied.

That is, in the relationship between the force in the Z direction acting on the mover 101 and the position in the Z direction, although the gravity Fg is constant even when the position in the Z direction indicated by the horizontal axis changes as shown in FIG. 9D, the attraction force Fm generally has a relationship proportional to the square of the distance between the permanent magnet 103 and the coil 202. The mover 101 in the transport apparatus 1 according to the present embodiment operates only in a region in which a proportional relationship is sufficiently satisfied for the attraction force Fm. Accordingly, the attraction force Fm can be regarded as a force that satisfies a relationship of an approximate straight line as indicated by the dash-dotted line in the graph of FIG. 9D.

The mover 101 is stable at the position of equilibrium P0. However, when the mover 101 is positioned at a position higher than the position of equilibrium P0, the mover 101 tends to continue to rise due to the attraction force Fm. Further, when the mover 101 is positioned at a position lower than the position of equilibrium P0, the mover 101 tends to fall due to the gravity Fg. This characteristic of the mover 101 is opposite to a general spring characteristic (positive spring characteristic). Thus, this characteristic of the mover 101 is referred to a negative spring characteristic. The mover 101 may have the negative spring characteristic in the Z direction, the Wx direction, and the Wy direction. In this case, the inclination of the attraction force Fm in the graph of FIG. 9D is referred to as negative spring constant or magnetic spring constant Kmag. The magnetic spring constant Kmag can be obtained from a relationship between an actual levitation height of the mover 101 and the instruction torque in the Z direction, and can further be calculated through magnetic circuit simulation in advance.

In the Wx direction, the position at which an R-side attraction force FmR and an L-side attraction force FmL are balanced with each other as illustrated in FIG. 9A is the position of equilibrium P0. The R-side attraction force FmR is a magnetic attraction force caused by the R-side permanent magnet 103R. The L-side attraction force FmL is a magnetic attraction force caused by the L-side permanent magnet 103L. Also in the Wy direction, the position at which the attraction forces around the origin Oc which is the position of the center of gravity of the mover 101 are similarly balanced with each other is the position of equilibrium.

The zero power control is a control method applicable only in a control direction in which the mover 101 has the negative spring characteristic. In the present embodiment, when the mover attitude control function 403 outputs positive torque, that is, when the mover 101 is present at a position lower than the position of equilibrium, the torque control function 605 calculates the operation amount “d” for updating the target position of the mover 101 in the positive direction. Further, when the mover attitude control function 403 outputs negative torque, that is, when the mover 101 is present at a position higher than the position of equilibrium, the torque control function 605 calculates the operation amount “d” for updating the target position of the mover 101 in the negative direction. In this manner, the torque control function 605 causes the mover 101 to follow the position of equilibrium. In the present embodiment, the zero power control is used in the Z direction, the Wx direction, and the Wy direction which are control directions in which the mover 101 has the negative spring characteristic.

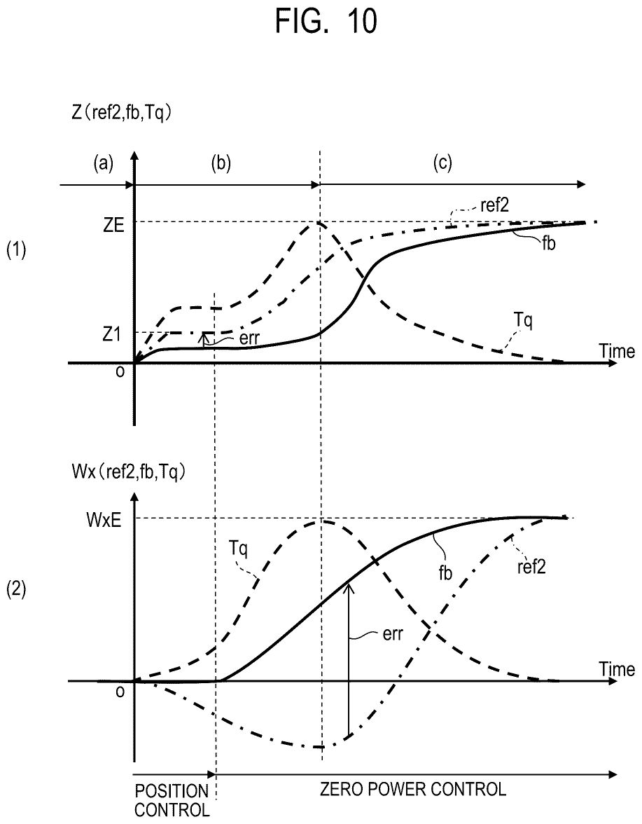

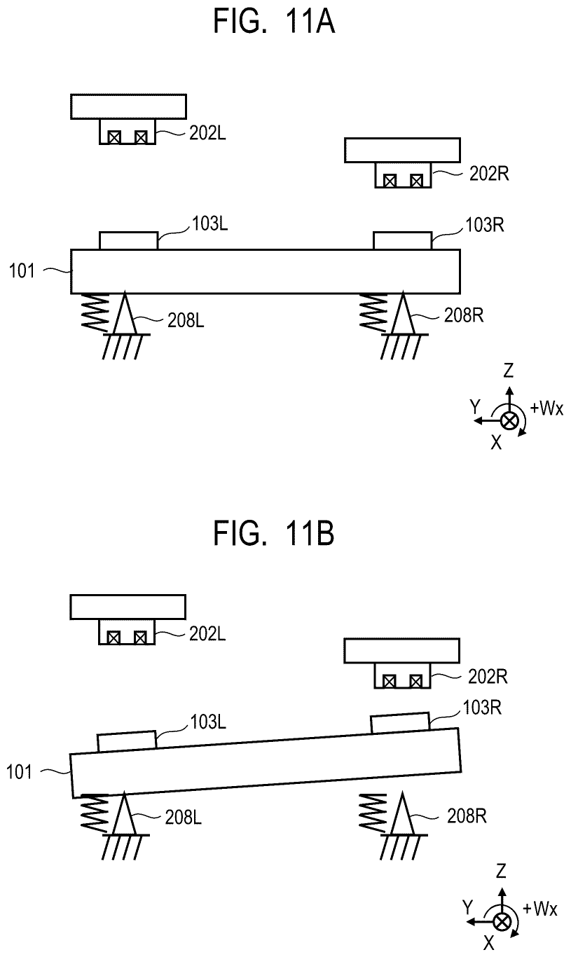

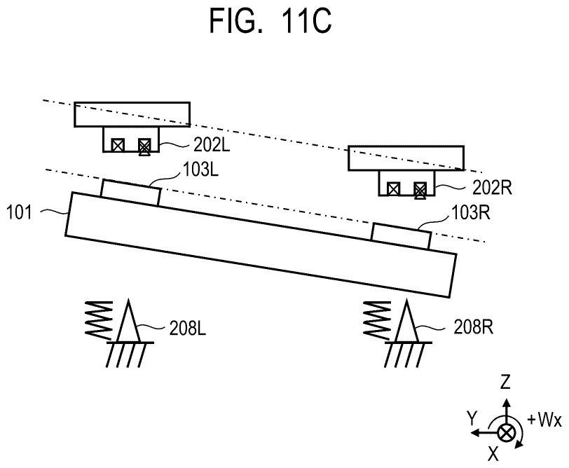

Next, a control method of stably levitating the mover 101 through use of the zero power control is described. Specifically, a flow of transition from the contact state to the non-contact state of the mover 101 through use of the zero power control (hereinafter referred to as “levitation sequence”) is described with reference to FIG. 10 and FIG. 11A to FIG. 11C. In this case, for the sake of simplicity, the Z direction and the Wx direction are focused and described as the control directions using the zero power control.

FIG. 10 is a graph showing the transition of the position in the Z direction and the position in the Wx direction of the mover 101 during the levitation sequence. In FIG. 10, the vertical axis of the graph of the upper part (1) indicates displacement in the Z direction, and the vertical axis of the graph of the lower part (2) indicates displacement in the Wx direction. The horizontal axis of both of the graphs indicates time. Further, in both of the graphs, the solid line indicates an actual position and attitude “fb” of the mover 101, the dash-dotted line indicates the target value ref2, and the broken line indicates the application torque Tq. The position instruction target value ref1 given when the position control is performed in the Z direction is represented by Z1. A position of equilibrium ZE in the Z direction and a position of equilibrium WxE in the Wx direction are positions to which the target value ref2 updated by the zero power control converges.

FIG. 11A to FIG. 11C are schematic views illustrating the attitude of the mover 101 corresponding to sections (a) to (c) in the horizontal axis representing time of FIG. 10. In this case, it is assumed that the mounting height of the R-side coil 202R opposed to the R-side permanent magnet 103R is lower than the mounting height of the L-side coil 202L opposed to the L-side permanent magnet 103L, and the R-side magnetic attraction force is larger than the L-side magnetic attraction force.

First, it is assumed that the transport apparatus 1 is powered off, and the mover 101 is placed on the lower guide 208. At this time, the mover 101 is in a state as illustrated in FIG. 11A.

At a time 0, the transport apparatus 1 is powered on, and the levitation sequence is started. In response thereto, the integration controller 301 starts the processing of the control blocks illustrated in FIG. 6.

First, the integration controller 301 sets Z1 for the position instruction target value ref1 in the Z direction. Z1 is a value set in order to determine the direction of the torque required for levitating the mover 101, and is a value smaller than the position of equilibrium ZE. At this time, the integration controller 301 sets the position at the time point of the time 0 so as to maintain the current attitude, as the position instruction target value ref1 in each of the Wx direction and the Wy direction. The integration controller 301 sets the position instruction target value like a ramp function. At this time, the switch 606 outputs 0, and thus “target value ref2”=ref1 is obtained. That is, the mover 101 is controlled by the position control. In this manner, the integration controller 301 starts the position control with respect to the mover 101 in the Z direction that is the levitation direction in which the mover 101 is levitated from the lower guide 208 when the mover 101 is in contact with the lower guide 208.

When Z1 is set as the position instruction target value ref1 in the Z direction and the position instruction in the Z direction is given, “fb” is raised toward Z1 in the Z direction, but the mover 101 receives a vertically downward force due to gravity. Accordingly, “fb” has a deviation “err” caused between “fb” and the target value ref2. Further, the mover 101 starts to rise from the R-side having a stronger magnetic attraction force. Accordingly, as illustrated in FIG. 11B, the mover 101 is in non-contact with the R-side lower guide 208R, and takes an attitude that is levitated on one side and is in contact with the L-side lower guide 208L. At this time, “fb” in the Wx direction changes in the negative direction, and the deviation “err” is caused between “fb” and the target value ref2.

After the position instruction is completed and the position instruction target value ref1 in the Z direction reaches Z1, the switch 606 switches the output source to output the operation amount “d” as the output of the torque control function 605. In this manner, “target value ref2”=ref1+d is satisfied. In this manner, the integration controller 301 starts the zero power control with respect to the mover 101 in the Z direction and the Wx direction when the mover 101 is in contact with the lower guide 208L after the position control. That is, the integration controller 301 starts the zero power control in the Z direction and the Wx direction after the mover 101 is separated by the position control from the lower guide 208R which is one of the lower guides 208L and 208R. Note that the integration controller 301 can start the zero power control in at least one direction among the Z direction, the Wx direction, and the Wy direction.

In the zero power control, in order to reduce the application torque Tq, the target value is changed in the direction in which the deviation is caused. Accordingly, in the zero power control, the target value is updated in the positive direction in the Z direction, that is, the levitation direction. Further, in the zero power control, the target value is updated in the positive direction in the Wx direction, that is, a direction opposite to the direction in which the mover 101 is inclined. With the zero power control, the inclination of the mover 101 is increased as the mover 101 is raised in the Z direction. In addition to the change in the negative direction of “fb” in the Wx direction due to the inclination of the mover 101, the zero power control changes the target value to the positive direction, and hence the deviation “err” in the Wx direction is further increased. The mover attitude control function 403 increases the application torque Tq along with the increase in deviation. With the application torque Tq being increased, the inclination of the mover 101 is reduced, and the deviation “err” is gradually turned to decrease. In this case, when the zero power control is invalid, the application torque Tq is insufficient because a sufficient deviation “err” is not obtained. Thus, the inclination cannot be reduced, and the mover 101 may oscillate to cause failure of the levitation of the mover 101.

When the mover 101 is raised in a state of reducing the inclination, the mover 101 is gradually separated from the lower guide 208L, and transitions to the levitation state. With the zero power control, the target value ref2 converges to the position of equilibrium, and “fb” follows. At this time, as illustrated in FIG. 11C, the inclination of the mover 101 gradually comes closer to an angle formed by a difference between the height of the R-side coil 202R and the height of the L-side coil 202L. Then, “fb” reaches the position of equilibrium, and the levitation sequence is completed.

In this manner, after the position control, the integration controller 301 starts the zero power control with respect to the mover 101 when the mover 101 is in contact with the lower guide 208, to thereby levitate the mover 101 from the lower guide 208.

As described above, in the transport apparatus 1 according to the present embodiment, the zero power control is started from the state in which the mover 101 is in contact with the lower guide 208, in the control direction having the negative spring characteristic. In this manner, according to the present embodiment, the oscillation of the mover 101 due to the natural vibration is suppressed or prevented, and hence the mover 101 can be stably levitated even when the mover 101 has a large size and a low rigidity.

Note that, in the present embodiment, after Z1 that is small to the extent that the mover 101 is not brought into the non-contact state is given as the target value of the position instruction, the switching from the position control to the zero power control is performed so that the zero power control is started under the contact state of the mover 101. However, this switching from the position control to the zero power control may be performed under other conditions. For example, a sensor for detecting contact between the lower guide 208 and the mover 101 can be provided to the lower guide 208, and the switching from the position control to the zero power control can be performed under a condition in which the sensor has detected that the mover 101 had been brought into the non-contact state from any one of the lower guides 208.

Also note that, in the present embodiment, the levitation direction of the mover 101 is regarded as the positive direction in the Z direction, but the present disclosure is not limited thereto. For example, even when the levitation direction is the negative direction in the Z direction, that is, even when the levitation sequence is started from a state in which the mover 101 is attracted to the upper guide 207 by the magnetic attraction force, the control method of performing the zero power control is applicable, similar to the above-mentioned case. Further, as long as the control direction is a direction in which the zero power control is applicable, the control method of performing the zero power control is applicable, similar to the above-mentioned case, and the axis of the levitation direction of the mover 101 is not limited to the Z direction. For example, also for an apparatus for levitating, in a right-left direction, a mover including a magnetic body arranged in a form of being sandwiched between coils arranged on right and left sides, the zero power control may be performed by a levitation sequence similar to that described above so that the mover can be stably levitated.

Also note that, in the present embodiment, description has been given of, as an example, the case in which a magnetic force acting between the permanent magnet 103 and the coil 202 is used as the levitation force for levitating the mover 101, but the present disclosure is not limited thereto. The mover 101 is only required to be configured to be levitated by a magnetic force acting between a first magnetic force unit included in the mover 101 and a second magnetic force unit included in the stator 201. In this case, it is only required that one of the first magnetic force unit or the second magnetic force unit include the permanent magnet 103, and another one thereof include the coil 202.

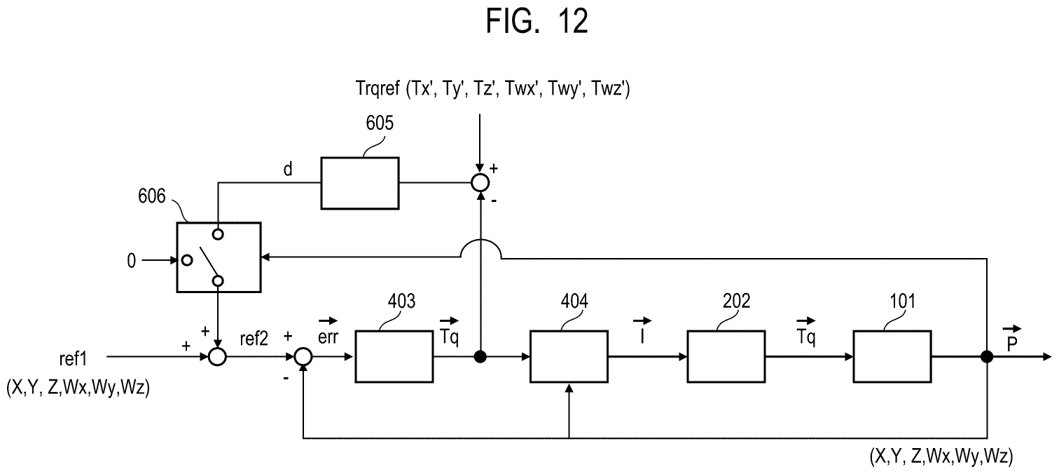

A magnetic levitation apparatus according to a second embodiment of the present disclosure is described with reference to FIG. 12 to FIG. 14. Also in the second embodiment, a transport apparatus is described as an example of the magnetic levitation apparatus. Further, components similar to those in the above-mentioned first embodiment are denoted by the same reference symbols, and description thereof is omitted or simplified.

The configuration of the transport apparatus 1 according to the present embodiment is similar to the configuration of the transport apparatus 1 according to the first embodiment. The transport apparatus 1 according to the present embodiment has a feature in that the condition for starting the zero power control is determined from a magnitude relationship between the spring constant of the lower guide 208 in contact with the mover 101 and the magnetic spring constant.

First, the method of controlling the mover 101 to be executed by the integration controller 301 in the transport apparatus 1 according to the present embodiment is described with reference to FIG. 12. FIG. 12 is a schematic view illustrating control blocks for controlling the position and attitude of the mover 101 in the transport apparatus 1 according to the present embodiment. The integration controller 301 executes control through the control blocks illustrated in FIG. 12.

In FIG. 12, the position and attitude P of the mover 101 has components of (X, Y, Z, Wx, Wy, Wz). The position instruction target value ref1 is used to give an instruction of a target value of (X, Y, Z, Wx, Wy, Wz). The deviation “err” is a deviation between the position instruction target value ref1 and the position and attitude P.

The mover attitude control function 403 calculates the desired application torque Tq from the magnitude of the deviation “err,” the change in the deviation “err,” the integrated value of the deviation “err,” and the like.

The coil current calculation function 404 calculates the desired coil current I to be applied to the coil 202 in order to apply the application torque Tq to the mover 101, based on the application torque Tq and the position and attitude P. When the coil current I calculated as described above is applied to the coil 202, the application torque Tq acts on the mover 101 to change the position and attitude P of the mover 101 again.

Further, the integration controller 301 can further execute processing using the torque control function 605 to control the torque to be applied to the mover 101. The torque control function 605 calculates the operation amount “d” to the target value ref2, from the integrated value of the difference between the application torque Tq and the instruction torque Trqref. Even in the present embodiment, similar to the first embodiment, the integration controller 301 can set the components of the instruction torque Trqref, Tz′, Twx′, and Twy′ to zero, so as to use the torque control function 605 as a function for performing the zero power control.

Further, the integration controller 301 uses the switch 606 as the switching unit for switching between the position control and the zero power control as the control to be performed on the mover 101. In the present embodiment, the switch 606 uses the value of the position and attitude P of the mover 101 to determine the contact state between the mover 101 and the lower guide 208, and compares the magnitude relationship between the spring constant of the lower guide 208 and the magnetic spring constant. As a result of the comparison, the switch 606 outputs the value 0 when the magnetic spring constant is equal to or smaller than the spring constant of the lower guide 208, and outputs “d” when the magnetic spring constant is larger than the spring constant of the lower guide 208. The output of the switch 606 is added to the position instruction target value ref1. In this manner, the target value of the position and attitude of the mover 101 is updated from ref1 to ref2.

In the control blocks illustrated in FIG. 12, when the output of the switch 606 is the value 0, the position and attitude of the mover 101 is controlled by the position control, and, when the output of the switch 606 is the operation amount “d”, the position and attitude of the mover 101 is controlled by the zero power control. With the control blocks being formed as described above, the position and attitude of the mover 101 can be controlled to the desired position and attitude.

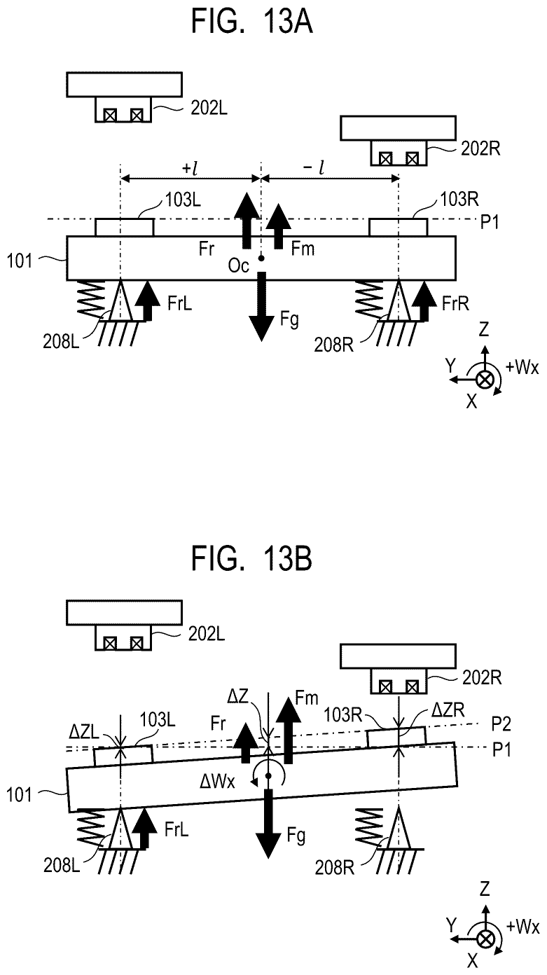

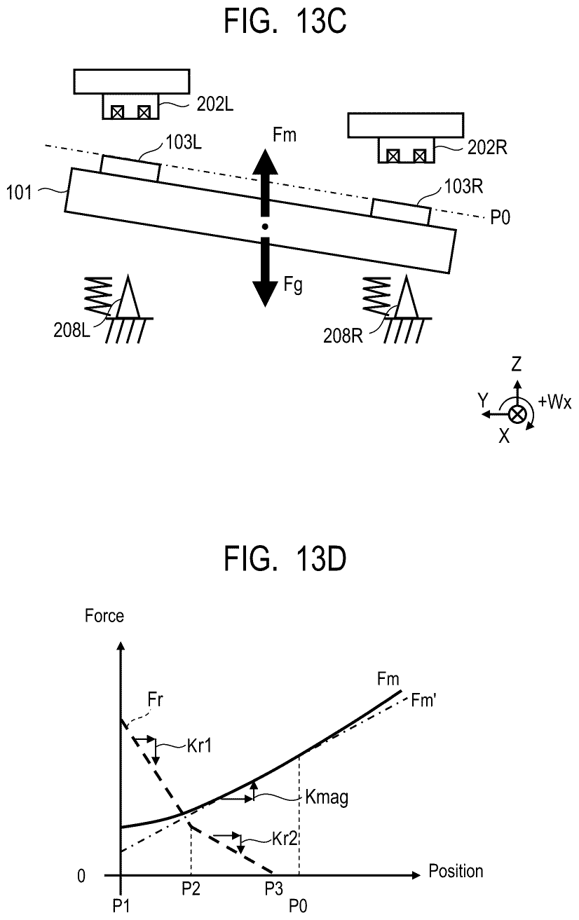

Next, a relationship between the attraction force and a reaction force received by the mover 101 from the lower guide 208 at each height of the mover 101 in the transport apparatus 1 is described with reference to FIG. 13A to FIG. 13D. In this case, it is assumed that the mounting height of the R-side coil 202R opposed to the R-side permanent magnet 103R is lower than the mounting height of the L-side coil 202L opposed to the L-side permanent magnet 103L, and the R-side magnetic attraction force is larger than the L-side magnetic attraction force.

FIG. 13A is a schematic view illustrating a state in which, in a case in which, for example, the transport apparatus 1 is powered off, the mover 101 is placed on the lower guide 208 under a state in which the mover 101 is not controlled. The position of the mover 101 in the Z direction at this time is represented by P1. Further, a distance in the Y direction from the center of the mover 101 to a center axis of the lower guide 208L along the Z direction is represented by +1, and a distance in the Y direction from the center of the mover 101 to a center axis of the lower guide 208R along the Z direction is represented by −1. A reaction force Fr from the lower guide 208 is a sum of a reaction force FrL from the L-side lower guide 208L and a reaction force FrR from the R-side lower guide 208R. In the state illustrated in FIG. 13A, the gravity Fg acting on the mover 101 is balanced with the sum of the reaction force Fr from the lower guide 208 and the attraction force Fm.

FIG. 13B is a schematic view illustrating a state in which the levitation sequence is started and the mover 101 is transitioned to the levitation state. The position of the mover 101 in the Z direction at this time is represented by P2. A change amount of a height of the center of gravity in the Z direction of the mover 101 when the mover 101 has transitioned from the position P1 to the position P2 is represented by ΔZ, and a change amount thereof in the Wx direction is represented by ΔWx. Further, a change amount of the position of the mover 101 in the Z direction on the center axis of the lower guide 208R is represented by ΔZR, and a change amount of the position of the mover 101 in the Z direction on the center axis of the lower guide 208L is represented by ΔZL. Those ΔZR and ΔZL can be calculated by the Equations (1) and (2):

$$Δ ZR = Δ Z - 1 * sin ( Δ Wx ) \qquad ( 1 )$$

$$Δ ZL = Δ Z + 1 * sin ( Δ Wx ) \qquad ( 2 )$$

In response to the position instruction given in the Z direction, the mover 101 starts to rise from the R-side having a stronger magnetic attraction force. Accordingly, the mover 101 is in non-contact with the R-side lower guide 208R, and takes an attitude that is levitated on one side and is in contact with the L-side lower guide 208L. At this time, ΔZ<ΔZR is satisfied. Further, when the elastic deformation of the lower guide 208L is also considered, it can be said that ΔZL≤0 is satisfied.

FIG. 13C is a schematic view illustrating a state in which the levitation sequence has been completed and the mover 101 has reached the position of equilibrium P0 in the Z direction. The mover 101 reaches the position of equilibrium P0 via a position P3 in the Z direction (see FIG. 13D) at which the mover 101 is in non-contact with the lower guide 208R and the lower guide 208L.

Now, the relationship between the magnetic spring constant Kmag and each of the spring constants of the lower guide 208R and the lower guide 208L at the positions of the mover 101 illustrated in FIG. 13A to FIG. 13C referred to above is described with reference to FIG. 13D. In this case, each of the spring constants of the lower guide 208R and the lower guide 208L is represented by Kr. FIG. 13D is a graph showing the relationship between the magnetic spring constant Kmag and each of the spring constants of the lower guide 208R and the lower guide 208L. The vertical axis of the graph of FIG. 13D represents force, and the horizontal axis thereof represents position in the Z direction. In the graph, the solid line indicates the attraction force Fm. The mover 101 in the transport apparatus 1 according to the present embodiment operates only in a region in which a proportional relationship is sufficiently satisfied for the attraction force Fm. Accordingly, the attraction force Fm can be regarded as a force that satisfies a relationship of an approximate straight line Fm′ as indicated by the dash-dotted line in the graph of FIG. 13D. The inclination of the straight line Fm′ indicates the magnetic spring constant Kmag. In the graph, the broken line indicates the reaction force Fr received by the mover 101 from the lower guide 208. An inclination of the straight line Fr in a section from the position P1 to the position P2 is represented by a spring constant Kr1, and an inclination of the straight line Fr in a section from the position P2 to the position P3 is represented by a spring constant Kr2.

The mover 101 abuts against two points, that is, the lower guide 208L and the lower guide 208R at the position P1. At this time, the spring constant of the entire lower guide 208 is represented by Kr1=Kr*2.

When the position of the mover 101 in the Z direction transitions from the position P1 to the position P2, the mover 101 is brought into a state of abutting against the lower guide 208L at one point. Accordingly, the spring constant of the entire lower guide 208 at this time is Kr2=Kr. At this time, the relationship between the magnetic spring constant Kmag and the spring constant of the entire lower guide 208 is represented by Kmag>Kr2, and the negative spring characteristic becomes dominant. As described in the first embodiment, the zero power control is a control method applicable only in a control direction having the negative spring characteristic. Thus, when the mover 101 is at a position satisfying Kmag>Kr2, the zero power control can be performed even when the mover 101 is in contact with the lower guide 208.

The position P3 is a position at which the reaction force Fr received by the mover 101 from the lower guide 208 becomes zero. That is, the position P3 is a position at which the mover 101 is brought into non-contact with the lower guide 208R and the lower guide 208L.

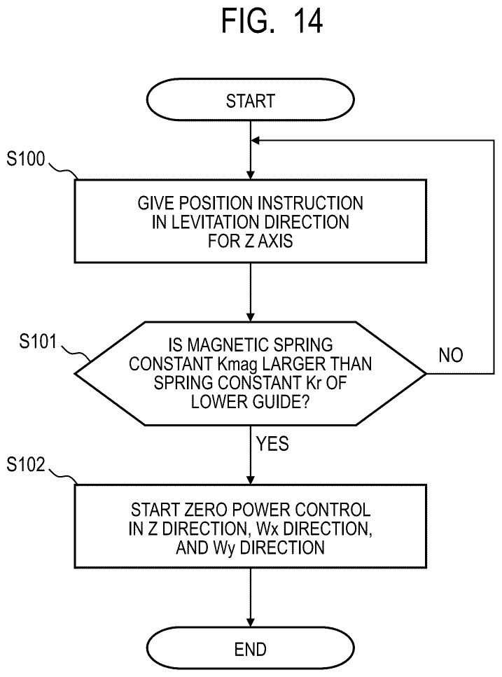

Next, the levitation sequence of the mover 101 in the transport apparatus 1 according to the present embodiment is described with reference to FIG. 14. FIG. 14 is a flow chart illustrating the levitation sequence of the mover 101 in the transport apparatus 1 according to the present embodiment.

It is assumed that, in an initial state from which the levitation sequence is started, the mover 101 is placed on the lower guide 208. Further, it is assumed that the spring constant Kr of the lower guide 208 and the magnetic spring constant Kmag are prepared in advance through simulation, measurement, or the like.

First, the integration controller 301 executes Step S100 to give a position instruction for levitating the mover 101 in the Z direction which is the levitation direction by the position control. At this time, the integration controller 301 gives the position instruction as a ramp function, and it is assumed that the target value thereof is sufficiently smaller than the position of equilibrium.

Next, the integration controller 301 executes Step S101 to compare, at the current position of the mover 101, which of the magnetic spring constant Kmag or the spring constant of the entire lower guide 208 is larger. The spring constant of the entire lower guide 208 changes based on how many lower guides 208 are in contact with the mover 101 as described above.

Now, a method of distinguishing the lower guide 208 in contact with the mover 101 is described while taking the state illustrated in FIG. 13B as an example. In the state illustrated in FIG. 13B, the position instruction is given in the Z direction, which is the levitation direction, and hence ΔZ≠0 is satisfied. Further, in this state, ΔZR>ΔZ and ΔZL≤0 are satisfied. When those three expressions are satisfied, the integration controller 301 can determine that the mover 101 is in contact with the lower guide 208L. A similar relationship is satisfied also for the lower guide 208R. Accordingly, when ΔZ≠0 is satisfied and ΔZL>ΔZ and ΔZR≤0 are satisfied, the integration controller 301 can determine that the mover 101 is in contact with the lower guide 208R. The sum of the spring constants of the lower guides 208 in contact with the mover 101 becomes the spring constant of the entire lower guide 208.

When it is determined that the magnetic spring constant Kmag is equal to or smaller than the spring constant of the entire lower guide 208 (Step S101, NO), the integration controller 301 executes Step S100 again to further raise the position of the mover 101 in the Z direction.

Meanwhile, when it is determined that the magnetic spring constant Kmag is larger than the spring constant of the entire lower guide 208 (Step S101, YES), the integration controller 301 executes Step S102.

In Step S102, the integration controller 301 starts the zero power control of the mover 101 in the Z direction, the Wx direction, and the Wy direction. When the zero power control is started, the mover 101 eventually reaches the position of equilibrium. The levitation sequence is completed when the mover 101 reaches the position of equilibrium.

As described above, in the transport apparatus 1 according to the present embodiment, from the state in which the mover 101 is in contact with the lower guide 208, the zero power control is started in the control direction having the negative spring characteristic. In this manner, according to the present embodiment, the oscillation of the mover 101 due to the natural vibration is suppressed or prevented, and hence the mover 101 can be stably levitated even when the mover 101 has a large size and a low rigidity.

Note that, in the present embodiment, the case in which the mover 101 is supported in contact by two lower guides 208 has been described as an example, but the number of lower guides 208 to be in contact with the mover 101 is not limited thereto. For example, consideration is made of a case in which the lower guide 208 is arranged in the depth direction of the drawing sheet of FIG. 13A to FIG. 13C. In this case, through use of the distance from the center of the mover 101 to the lower guide 208 and the change amounts of the mover 101 in the Z direction and the Wy direction, the contact state between the mover 101 and the lower guide 208 can be determined, and the spring constant of the entire lower guide 208 can be obtained.

Also note that, in the present embodiment, the position and attitude of the mover 101 is used to determine the number of lower guides 208 in contact with the mover 101, but the present disclosure is not limited thereto. For example, a sensor for detecting the contact between the lower guide 208 and the mover 101 may be provided on the lower guide 208, and the number of lower guides 208 in contact with the mover 101 may be determined based on the output of the sensor.

Also note that, the method of controlling the mover 101 by the zero power control in the present embodiment is also applicable to a case in which, similar to the first embodiment, the mover 101 is levitated in other levitation directions such as the negative direction in the Z direction and the right-left direction, in addition to the positive direction in the Z direction.

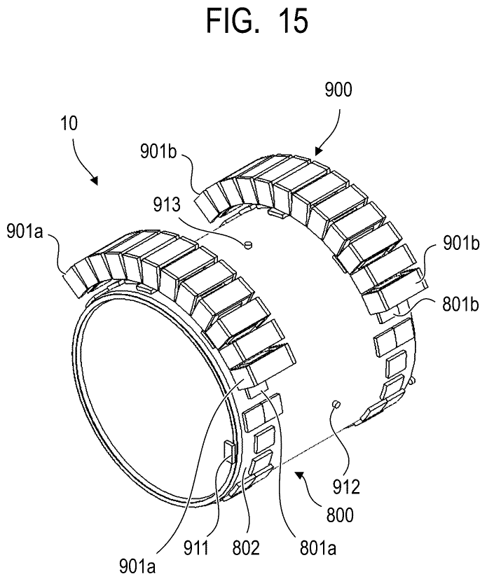

A magnetic levitation apparatus according to a third embodiment of the present disclosure is described with reference to FIG. 15. In the present embodiment, a rotational drive apparatus is described as an example of the magnetic levitation apparatus. FIG. 15 is a schematic view illustrating a rotational drive apparatus 10 according to the present embodiment, and is a view of the rotational drive apparatus 10 as viewed from diagonally above the rotational drive apparatus 10.

As illustrated in FIG. 15, the rotational drive apparatus 10 according to the third embedment includes a rotor 800 which is an example of the mover, and a stator 900. The rotor 800 includes a plurality of first permanent magnets 801a and a plurality of second permanent magnets 801b which are an example of a plurality of magnets, as a permanent magnet group which is an example of a magnet group. The stator 900 includes, as a coil group, a plurality of first coils 901a and a plurality of second coils 901b. Further, the stator 900 includes sensors 911, 912, and 913 for detecting displacement or attitude of the rotor 800.

The rotor 800 has a hollow cylindrical shape having, as a center axis, an axis along, for example, the horizontal direction which is a direction intersecting with the gravity direction. The rotor 800 is configured to be rotatable in a rotation direction about the center axis serving as a rotary axis. Note that the shape of the rotor 800 is not limited to the hollow cylindrical shape. The shape of the rotor 800 is only required to be a shape that allows rotation about the rotary axis along the direction intersecting with the gravity direction, and may be a different shape such as a column shape in accordance with, for example, a configuration of equipment using the rotation of the rotor 800.

The plurality of first permanent magnets 801a serving as the permanent magnet group are mounted and installed on an outer peripheral side surface of the rotor 800 on which a yoke 802 is installed, so as to be arranged side by side in one row circumferentially and equally along the rotation direction. The plurality of second permanent magnets 801b serving as the permanent magnet group are also mounted and installed on the outer peripheral side surface of the rotor 800 on which the yoke 802 is installed, so as to be arranged side by side in one row circumferentially and equally along the rotation direction. For example, the plurality of first permanent magnets 801a are installed on the outer peripheral side surface on one end side in the direction along the center axis of the rotor 800 so as to be arranged side by side circumferentially, and the plurality of second permanent magnets 801b are installed on the outer peripheral side surface on another end side in the direction along the center axis of the rotor 800 so as to be arranged side by side circumferentially. In this manner, the plurality of first permanent magnets 801a and the plurality of second permanent magnets 801b are arranged in the rotor 800.

In the stator 900, the plurality of first coils 901a and the plurality of second coils 901b are installed so as to be positioned above the rotor 800 in the gravity direction on the outer side of the rotor 800, and so as to be opposed to the first permanent magnets 801a and the second permanent magnets 801b, respectively. The plurality of first coils 901a are mounted at positions that can be opposed to the plurality of first permanent magnets 801a of the rotor 800, so as to be arranged side by side in one row in an arc shape and equally along the rotation direction. The plurality of second coils 901b are mounted at positions that can be opposed to the plurality of second permanent magnets 801b of the rotor 800, so as to be arranged side by side in one row in an arc shape and equally along the rotation direction. In this manner, the plurality of first coils 901a and the plurality of second coils 901b are arranged in the stator 900.

In this manner, the rotor 800 is arranged below the plurality of first coils 901a and the plurality of second coils 901b in the gravity direction. When a current is applied to the first coil 901a and the second coil 901b by the controller, an electromagnetic force is generated between the rotor 800 and each of the first coil 901a and the second coil 901b to act on the rotor 800. In this manner, levitation control and rotation control of the rotor 800 are performed. The rotor 800 rotates about the rotary axis by the rotation control while being levitated in the gravity direction by the levitation control. Before levitation, the rotor 800 is placed on a plurality of guides, to be supported by the plurality of guides.

As described above, the rotational drive apparatus 10 according to the present embodiment includes the rotor 800 having the rotary axis intersecting with the gravity direction, and the stator 900 arranged above the rotor 800 in the gravity direction, and the rotor 800 is rotated while the rotor 800 is magnetically levitated in the gravity direction. Even when this rotor 800 is to be levitated, the rotor 800 can be levitated by executing, by the controller, a control method using zero power control similar to that in the first embodiment or the second embodiment. In this manner, the oscillation of the rotor 800 is suppressed or prevented, and hence the rotor 800 can be stably levitated even when the rotor 800 has a large size and a low rigidity.

Note that, in the present embodiment, description has been given of, as an example, the case in which a magnetic force acting between the first permanent magnets 801a and the first coils 901a and between the second permanent magnets 801b and the second coils 901b is used as a levitation force for levitating the rotor 800, but the present disclosure is not limited thereto. The rotor 800 is only required to be configured to be levitated by a magnetic force acting between a first magnetic force unit included in the rotor 800 and a second magnetic force unit included in the stator 900. In this case, it is only required that one of the first magnetic force unit or the second magnetic force unit include the first permanent magnets 801a and the second permanent magnets 801b, and another one thereof include the first coils 901a and the second coils 901b.

The magnetic levitation apparatus according to the present disclosure can be used in other embodiments a manufacturing system for manufacturing an article such as electronic equipment, as a transport apparatus for transporting a workpiece together with a mover to a work region of each process apparatus such as a machine tool for subjecting the workpiece that becomes the article to each work step. The process apparatus for executing each work step may be any apparatus such as an apparatus for mounting components on the workpiece or an apparatus for executing coating, in addition to the vapor deposition apparatus described above. Further, the article to be manufactured is not limited to a specific article, and may be any component. As described above, through use of the magnetic levitation apparatus according to the present disclosure, the workpiece can be transported to the work region, and the workpiece transported to the work region can be subjected to the work step so that the article can be manufactured.

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

According to the present disclosure, a mover can be stably levitated even when the mover has a large size and a low rigidity.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of and priority to Japanese Patent Application No. 2024-059199, filed Apr. 1, 2024, the entirety of which is incorporated herein by reference.

What is claimed is:

1. A magnetic levitation apparatus comprising:
a mover including a first magnetic force unit;
a second magnetic force unit positioned opposed to the first magnetic force unit, wherein a magnetic force acts between the second magnetic force unit and the first magnetic force unit;
a guide unit configured to support the mover; and
a control unit configured to control a position and an attitude of the mover,
wherein one of the first magnetic force unit and the second magnetic force unit includes a coil, and another one of the first magnetic force unit and the second magnetic force unit includes a magnet,
wherein the control unit is configured to control a current flowing through the coil to control the position and the attitude of the mover, and
wherein the control unit is configured to start, when the mover is in contact with the guide unit, position control with respect to the mover in a levitation direction, and start, when the mover is in contact with the guide unit after the position control, zero power control with respect to the mover to levitate the mover from the guide unit.

2. The magnetic levitation apparatus according to claim 1,
wherein the guide unit comprises a plurality of guide units, and
wherein the control unit is configured to start the zero power control after the mover is separated from any one of the plurality of guide units by the position control.

3. The magnetic levitation apparatus according to claim 1, wherein the control unit is configured to control the position and the attitude of the mover in a first direction which is the levitation direction, a second direction intersecting with the first direction, a third direction intersecting with the first direction and the second direction, a fourth direction which is a rotation direction about a first axis along the first direction, a fifth direction which is a rotation direction about a second axis along the second direction, and a sixth direction which is a rotation direction about a third axis along the third direction.

4. The magnetic levitation apparatus according to claim 3, wherein the first direction is a vertical direction.

5. The magnetic levitation apparatus according to claim 3, wherein the second direction is a horizontal direction and the third direction is another horizontal direction.

6. The magnetic levitation apparatus according to claim 3, wherein the control unit is configured to start the zero power control in at least one of the first direction, the fifth direction, and the sixth direction.

7. The magnetic levitation apparatus according to claim 6, wherein the mover has a negative spring characteristic in at least one of the first direction, the fifth direction, and the sixth direction.

8. The magnetic levitation apparatus according to claim 1, wherein the control unit is configured to start the zero power control when a magnetic spring constant of the mover is greater than a spring constant of the guide unit.

9. The magnetic levitation apparatus according to claim 1,
wherein the first magnetic force unit includes the magnet, and
wherein the second magnetic force unit includes the coil.

10. The magnetic levitation apparatus according to claim 1, wherein the mover is movable in a direction intersecting with the levitation direction while being levitated in the levitation direction.

11. The magnetic levitation apparatus according to claim 1, wherein the magnet is a permanent magnet.

12. A method of controlling a magnetic levitation apparatus, the magnetic levitation apparatus including:
a mover including a first magnetic force unit;
a second magnetic force unit positioned opposed to the first magnetic force unit, wherein a magnetic force acts between the second magnetic force unit and the first magnetic force unit; and
a guide unit configured to support the mover,
wherein one of the first magnetic force unit and the second magnetic force unit includes a coil, another one of the first magnetic force unit and the second magnetic force unit includes a magnet,
the method comprising:
controlling, by a control unit, a current flowing through the coil, to control a position and an attitude of the mover;
starting, by the control unit, when the mover is in contact with the guide unit, position control with respect to the mover in a levitation direction; and
starting, by the control unit, when the mover is in contact with the guide unit after the position control, zero power control with respect to the mover to levitate the mover from the guide unit.

13. A manufacturing system comprising:
the magnetic levitation apparatus according to claim 1; and
a process apparatus configured to work a workpiece being transported by the mover.

14. The manufacturing system according to claim 13,
wherein the workpiece is a substrate, and
wherein the process apparatus is a film formation apparatus configured to form a film on the substrate.

15. A method of manufacturing an article using the manufacturing system according to claim 13, the method comprising:
transporting the workpiece by the mover, and
working, by the process apparatus, the workpiece being transported by the mover.
